(19) United States
(12) Patent Application Publication
(10) Pub. No.: US 2023/0337506 A1
(43) Pub. Date: Oct. 19, 2023

(54) DISPLAY APPARATUS AND COVER WINDOW FOR DISPLAY APPARATUS

(71) Applicant: SAMSUNG DISPLAY CO., LTD., Yongin-si (KR)

(72) Inventors: Youngmin PARK, Yongin-si (KR); Donghyeon LEE, Yongin-si (KR); Junwoo YOU, Yongin-si (KR)

(21) Appl. No.: 18/133,994

(22) Filed: Apr. 12, 2023

(30) Foreign Application Priority Data
Apr. 15, 2022 (KR) 10-2022-0047183

(51) Int. Cl. H10K 59/80

(52) U.S. Cl. CPC H10K 59/87; H10K 59/879; H10K 2102/311

(57) ABSTRACT

A display apparatus includes: a display panel including a display portion and a plurality of connection portions connected to the display portion and extending in different directions; and a cover window disposed on the display panel. The cover window includes: a first member defining a plurality of opening patterns therein; and a second member disposed in the plurality of opening patterns, and a modulus of the first member is greater than a modulus of the second member.

This application claims priority to Korean Patent Application No. 10-2022-0047183, filed on Apr. 15, 2022, and all the benefits accruing therefrom under 35 U.S.C. § 119, the content of which in its entirety is herein incorporated by reference.

### BACKGROUND

### 1. Field

One or more embodiments relate to display apparatuses and cover windows for display apparatuses.

### 2. Description of the Related Art

A mobility-based electronic device has been widely used. In addition to a compact electronic device, such as mobile phones, a tablet personal computer (“PC”) has been widely used as a mobile electronic device.

The mobile electronic device includes a display apparatus to provide a user with various functions, for example, visual information, such as an image or a video. As other parts for driving the display apparatus are miniaturized, a portion taken by the display apparatus in the electronic device has been gradually increased.

A flexible display apparatus that is bendable, foldable, or rollable has been researched and developed. Furthermore, research and development about a stretchable display apparatus that is changeable into various shapes have been actively conducted.

### SUMMARY

One or more embodiments include display apparatuses with improved flexibility and cover windows for the display apparatuses.

Additional aspects will be set forth in part in the description which follows and, in part, will be apparent from the description, or may be learned by practice of the presented embodiments of the disclosure.

According to one or more embodiments, a display apparatus includes: a display panel including a display portion and a plurality of connection portions connected to the display portion and extending in different directions; and a cover window disposed on the display panel, where the cover window includes: a first member defining a plurality of opening patterns therein; and a second member disposed in the plurality of opening patterns, and a modulus of the first member is greater than a modulus of the second member.

In an embodiment, each of the plurality of opening patterns may include a first opening extending in a first direction and a second opening formed in a first end of the first opening.

In an embodiment, each of the plurality of opening patterns may further include a third opening formed in a second end of the first opening opposite to the first end of the first opening.

In an embodiment, the plurality of opening patterns may be arranged parallel to the first direction, which is a longitudinal direction of the first opening.

In an embodiment, an interval between the plurality of opening patterns in the first direction may be less than the length of the first opening in the first direction.

In an embodiment, the length of the second opening in the first direction may be less than the length of the first opening in the first direction.

In an embodiment, the length of the third opening in the first direction may be less than the length of the first opening in the first direction.

In an embodiment, in a second direction perpendicular to the first direction, the width of the first opening may be less than each of the width of the second opening and the width of the third opening.

In an embodiment, the plurality of opening patterns may include a first opening pattern, a second opening pattern, and a third opening pattern, which are sequentially arranged and apart from one another in the second direction perpendicular to the first direction, a second opening of the first opening pattern and a second opening of the third opening pattern may be positioned on a virtual straight line in the second direction, and a first opening of the second opening pattern may be positioned between the second opening of the first opening pattern and the second opening of the third opening pattern.

In an embodiment, each of the second opening and the third opening may have a circular shape.

In an embodiment, the second opening and the third opening may have the same size.

In an embodiment, a modulus of the first member may be greater than 1 gigapascals (GPa) and less than 10 GPa.

In an embodiment, a modulus of the second member may be greater than 0 GPa and less than 0.1 GPa.

In an embodiment, a difference in a refractive index between the first member and the second member may be 0 to 3/1000.

In an embodiment, the first member may include glass, polyethylene terephthalate (“PET”), or transparent polyimide (“PI”).

In an embodiment, the second member may include thermoplastic polyurethane (“TPU”) or polydimethylsiloxane (“PDMS”).

In an embodiment, each of the plurality of opening patterns may include a plurality of first openings having a common end gathered at a center point of a corresponding opening pattern, and a plurality of second openings formed in opposite ends opposite to the common end of the plurality of first openings.

In an embodiment, an angle between the plurality of first openings may be 120 degrees (°).

In an embodiment, each of the plurality of second openings may be formed to point toward a center point of another opening pattern closest to the each of the plurality of second openings.

According to one or more embodiments, a cover window for a display panel disposed on the display panel includes: a first member defining a plurality of opening patterns therein, and a second member disposed in the plurality of opening patterns, where a modulus of the first member is greater than a modulus of the second member.

### BRIEF DESCRIPTION OF THE DRAWINGS

The above and other aspects, features, and advantages of certain embodiments of the disclosure will be more apparent from the following description, taken in conjunction with the accompanying drawings, in which:

FIG. 1 is a schematic cross-sectional view of a display apparatus according to an embodiment;

FIG. 2 is a schematic plan view of a display apparatus according to an embodiment;

FIG. 3 is a schematic equivalent circuit diagram of a pixel circuit applicable to a display apparatus according to an embodiment;

FIG. 4 is a schematic plan view of a display apparatus according to an embodiment, by enlarging a region A of FIG. 2;

FIG. 5 is a schematic cross-sectional view of a display apparatus according to an embodiment, taken along line B-B′ of FIG. 4;

FIG. 6 is a schematic cross-sectional view of a display apparatus according to an embodiment;

FIG. 7 is a schematic plan view of a cover window of a display apparatus, according to an embodiment;

FIG. 8A is a schematic plan view showing a state of the cover window of FIG. 7 before stretching;

FIG. 8B is a schematic plan view showing a state of the cover window of FIG. 7 after stretching;

FIG. 9 is a schematic plan view of a cover window according to another embodiment; and

FIG. 10 is a schematic plan view of a cover window according to still another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. “Or” means “and/or.” As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

According to an embodiment, display apparatuses having high contraction and elasticity may be implemented. Furthermore, display apparatuses capable of controlling deformation of a display panel according to contraction and stretching may be implemented. The scope of the disclosure is not limited by the effect.

Various modifications may be applied to the present embodiments, and particular embodiments will be illustrated in the drawings and described in the detailed description section. The effect and features of the present embodiments, and a method to achieve the same, will be clearer referring to the detailed descriptions below with the drawings. However, the present embodiments may be implemented in various forms, not by being limited to the embodiments presented below.

In the following embodiments, while such terms as “first,” “second,” etc., may be used to describe various components, such components must not be limited to the above terms. The above terms are used only to distinguish one component from another

In the following embodiments, the expression of singularity in the specification includes the expression of plurality unless clearly specified otherwise in context.

In the following embodiments, terms such as “include” or “comprise” may not be construed to necessarily include any and all constituent elements or steps described in the specification, but may be construed to exclude some of the constituent elements or steps or further include additional constituent elements or steps.

In the following embodiments, it will be understood that when a layer, region, or component is referred to as being “formed on” another layer, region, or component, it can be directly or indirectly formed on the other layer, region, or component.

In the drawings, sizes of components in the drawings may be exaggerated for convenience of explanation. For example, since sizes and thicknesses of components in the drawings are arbitrarily illustrated for convenience of explanation, the following embodiments are not limited thereto.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

In the following embodiments, the meaning that the wiring “extends in the first direction or the second direction” includes not only extending in a linear shape, but also extending in a zigzag or a curve along the first direction or the second direction.

In embodiments below, when referred to as “on a plane,” this means when an object part is viewed from above (i.e., plan view), and when it is referred to as “in a cross-section,” it means when the cross-section where the object part is cut vertically is viewed from the side. In the following embodiments, when referred to as “overlapping,” it includes overlapping “on a plane” or “in a cross-section.”

Hereinafter, the disclosure will be described in detail by explaining preferred embodiments of the disclosure with reference to the attached drawings. Like reference numerals in the drawings denote like elements.

A display apparatus may be used as a display screen of not only portable electronic apparatuses, such as mobile phones, smartphones, tablet personal computers (PCs), mobile communication terminals, electronic organizers, electronic books, portable multimedia players (“PMPs”), navigation devices, ultra mobile PCs (“UMPCs”), and the like, but also various products, such as televisions, notebook computers, monitors, billboards, Internet of things (“IoT”) device, and the like. Furthermore, a display apparatus according to an embodiment may be used in wearable devices, such as smart watches, watch phones, glasses-type displays, and head mounted displays (“HMDs”). Furthermore, a display apparatus according to an embodiment may be used as an instrument panel of a vehicle, a center information display (“CID”) disposed in the center fascia or dashboard of a vehicle, a room mirror display in lieu of a side mirror of a vehicle, or a display screen disposed at the rear surface of a front seat as an entertainment device for a rear seat of a vehicle.

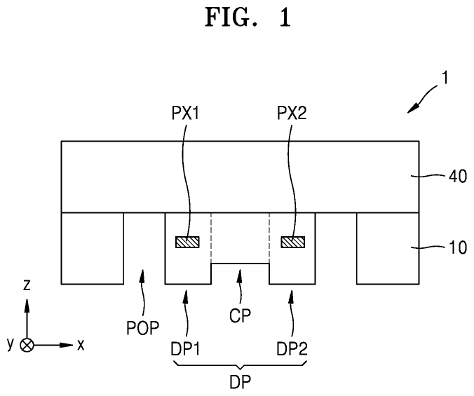

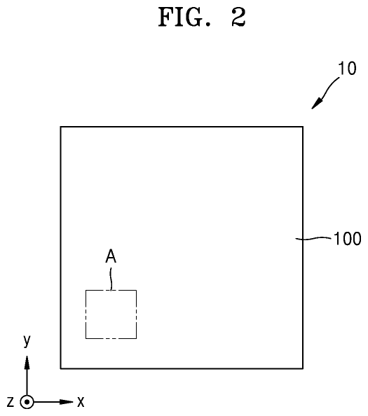

FIG. 1 is a schematic cross-sectional view of a display apparatus 1 according to an embodiment. FIG. 2 is a schematic plan view of the display apparatus 1 according to an embodiment. Here, the “plan view” is a view in z direction (i.e., thickness direction of the display apparatus 1).

Referring to FIG. 1, the display apparatus 1 may include a display panel 10 and a cover window 40. The cover window 40 may be disposed on the display panel 10.

The display panel 10 may display an image. The display panel 10 may include a plurality of pixels, for example, a first pixel PX1 and a second pixel PX2. The display panel 10 may display an image by using the plurality of pixels.

In an embodiment, each pixel may include a display element. The display panel 10 may include an organic light-emitting display panel using an organic light-emitting diode including an organic emission layer. Alternatively, the display panel 10 may include a light-emitting diode display panel using a light-emitting diode (“LED”). The size of the LED may be micro-scale or nano-scale. For example, the LED may include a micro LED. Alternatively, the LED may include a nanorod LED. The nanorod LED may include gallium nitride (GaN). In an embodiment, a color conversion layer may be disposed on a nanorod LED. The color conversion layer may include quantum dots. Alternatively, the display panel 10 may include a quantum dot light-emitting display panel using a quantum-dot light-emitting diode including a quantum-dot emission layer. Alternatively, the display panel 10 may include an inorganic light-emitting display panel using an inorganic light-emitting diode including an inorganic semiconductor. In the following description, a case in which the display panel 10 is an organic light-emitting display panel using an organic light-emitting diode as a display element is mainly described in detail.

The display panel 10 may include a first display portion DP1, a second display portion DP2, and a connection portion CP. The first pixel PX1 may be disposed in the first display portion DP1. The second pixel PX2 may be disposed in the second display portion DP2. The connection portion CP may be disposed between the first display portion DP1 and the second display portion DP2. Pixels may not be disposed in the connection portion CP. The connection portion CP may extend from the first display portion DP1 to the second display portion DP2.

A penetrating opening portion POP may be defined in the display panel 10. The penetrating opening portion POP may penetrate the display panel 10. The penetrating opening portion POP may be an area where no constituent element of the display panel 10 is disposed. The display panel 10 may include a plurality of penetrating opening portions POP. Accordingly, the display panel 10 may stretch and/or contract.

The cover window 40 may protect the display panel 10. In an embodiment, the cover window 40 may protect the display panel 10 while being easily bent depending on an external force without cracks occurring or the like. The cover window 40 may be attached to the display panel 10 by a transparent adhesive member, such as an optically clear adhesive film.

Referring to FIG. 2, the display panel 10 may include a substrate 100 and a multilayer film disposed on the substrate 100. In an embodiment, the display panel 10 may include the penetrating opening portion POP (see FIG. 1). The substrate 100 and the multilayer film may not be disposed in the penetrating opening portion POP. In other words, the penetrating opening portion POP may be an empty area of the display panel 10. The penetrating opening portion POP may include a plurality of penetrating opening portions POP in the display panel 10. As the penetrating opening portions POP are provided in the display panel 10, the flexibility of the display apparatus 1 (see FIG. 1) including the display panel 10 may be improved.

The substrate 100 may include glass or polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, and the like. The substrate 100 including polymer resin may be flexible, rollable, and bendable. The substrate 100 may have a multilayer structure in which a plurality of base layers including the above-described polymer resin and a plurality of barrier layers including an inorganic material are stacked.

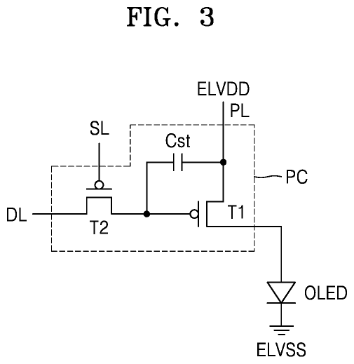

FIG. 3 is a schematic equivalent circuit diagram of a pixel circuit applicable to the display apparatus 1 according to an embodiment.

Referring to FIG. 3, a pixel circuit PC may be connected to a display element, for example, an organic light-emitting diode OLED. The pixel circuit PC may include a driving thin film transistor T1, a switching thin film transistor T2, and a storage capacitor Cst. The organic light-emitting diode OLED may emit red, green, or blue light, or red, green, blue, or white light.

The switching thin film transistor T2 is connected to a scan line SL and a data line DL, and may be configured to transmit a data signal or a data voltage input through the data line DL to the driving thin film transistor T1, based on a scan signal or a switching voltage input through the scan line SL. The storage capacitor Cst is connected to the switching thin film transistor T2 and a driving voltage line PL, and may be configured to store a voltage corresponding to a difference between the voltage received from the switching thin film transistor T2 and a first power voltage ELVDD supplied through the driving voltage line PL.

The driving thin film transistor T1 is connected to the driving voltage line PL and the storage capacitor Cst, and may be configured to control a driving current flowing from the driving voltage line PL to the organic light-emitting diode OLED, corresponding to a voltage value stored in the storage capacitor Cst. The organic light-emitting diode OLED may emit light having a certain luminance according to the driving current. A counter electrode of the organic light-emitting diode OLED may receive a second power voltage ELVSS.

Although FIG. 3 illustrates that the pixel circuit PC includes two thin film transistors and one storage capacitor, the pixel circuit PC may include three or more thin film transistors.

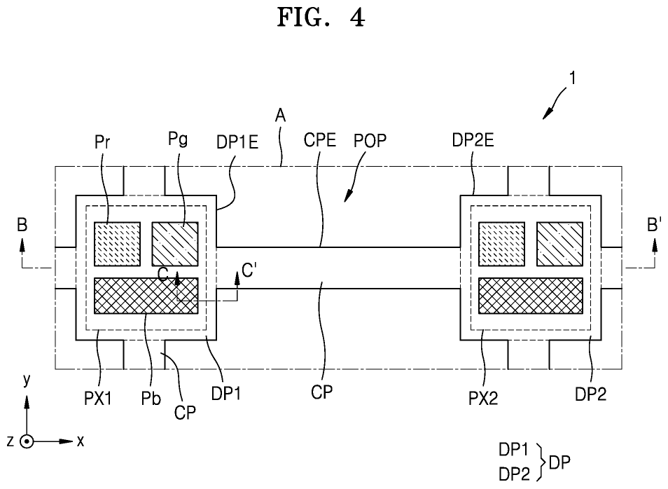

FIG. 4 is a schematic plan view of the display apparatus 1 according to an embodiment, by enlarging a region A of FIG. 2.

Referring to FIG. 4, the display apparatus 1 may include a display portion DP and the connection portion CP. The display portion DP may include the first display portion DP1 and the second display portion DP2. In an embodiment, the display apparatus 1 may include a plurality of first display portions DP1 and a plurality of second display portions DP2. Furthermore, the display apparatus 1 may include a plurality of the connection portions CP.

The first pixel PX1 may be disposed in the first display portion DP1. The first display portion DP1 may be disposed apart from the second display portion DP2. The first display portion DP1 may be connected to the connection portion CP. In an embodiment, the first display portion DP1 may be connected to at least one of the connection portions CP.

The second pixel PX2 may be disposed in the second display portion DP2. The second display portion DP2 may be disposed apart from the first display portion DP1. The second display portion DP2 may be connected to the connection portion CP. In an embodiment, the second display portion DP2 may be connected to at least one of the connection portions CP. The second display portion DP2 may have a structure similar to the first display portion DP1.

The connection portion CP may extend from the first display portion DP1 to the second display portion DP2. The first display portion DP1 and the second display portion DP2 may be connected to each other by the connection portion CP. In an embodiment, when the display apparatus 1 includes a plurality of connection portions CP, the plurality of connection portions CP may be connected to the first display portion DP1 and/or the second display portion DP2. Alternatively, the plurality of connection portions CP may extend from the first display portion DP1 and/or the second display portion DP2.

Any one of the connection portions CP may extend in a first direction. Another of the connection portions CP may extend in a second direction crossing the first direction. In an embodiment, the first direction and the second direction may be orthogonal to each other. For example, the first direction may include a +x direction or a −x direction of FIG. 4, and the second direction may include a +y direction or a −y direction of FIG. 4. Alternatively, the first direction and the second direction may form an acute angel or an obtuse angle with each other. In the following description, a case in which the first direction, for example, a +x direction or a −x direction, and the second direction, for example, a +y direction or a −y direction, are orthogonal to each other is mainly described in detail.

In an embodiment, the first display portion DP1 and the connection portion CP may be defined as one basic unit. In this case, the basic unit may be repeatedly disposed in the first direction, for example, the +x direction or the −x direction, and/or in the second direction, for example, the +y direction or the −y direction, and the display apparatus 1 may have a structure in which the repeatedly disposed basic units are connected to each other.

The penetrating opening portion POP may be defined in the display panel 10. The penetrating opening portion POP may penetrate the display panel 10. Accordingly, the penetrating opening portion POP may be an area where no constituent element of the display panel 10 is disposed. The display panel 10 may define a plurality of penetrating opening portions POP therein. Accordingly, the flexibility of the display panel 10 may be improved.

At least a portion of the penetrating opening portion POP may be defined by an edge DP1E of the first display portion DP1, an edge DP2E of the second display portion DP2, and an edge CPE of the connection portion CP. In an embodiment, the penetrating opening portion POP may have a closed curve shape. Alternatively, the penetrating opening portion POP may have an at least partially open shape.

The thickness of the first display portion DP1 and the thickness of the second display portion DP2 in z direction may each be greater than the thickness of the connection portion CP. Accordingly, even when strain occurs in the connection portion CP, the maximum value of strain occurring in the connection portion CP may be reduced.

The first pixel PX1 and the second pixel PX2 may each include a red sub-pixel Pr, a green sub-pixel Pg, and a blue sub-pixel Pb. The red sub-pixel Pr, the green sub-pixel Pg, and the blue sub-pixel Pb may emit red light, green light, and blue light, respectively. Alternatively, in another embodiment, the first pixel PX1 and the second pixel PX2 may each include the red sub-pixel Pr, the green sub-pixel Pg, the blue sub-pixel Pb, and a white sub-pixel. The red sub-pixel Pr, the green sub-pixel Pg, the blue sub-pixel Pb, and the white sub-pixel may emit red light, green light, blue light, and white light, respectively. In the following description, a case in which each of the first pixel PX1 and the second pixel PX2 includes the red sub-pixel Pr, the green sub-pixel Pg, and the blue sub-pixel Pb is mainly described in detail.

In an embodiment, the red sub-pixel Pr and the green sub-pixel Pg may each be arranged in a quadrangular shape, and the blue sub-pixel Pb may be arranged in a rectangular shape having a long side in the first direction, for example, the +x direction or the −x direction. In other words, the red sub-pixel Pr, the green sub-pixel Pg, and the blue sub-pixel Pb may be arranged such that a side of the red sub-pixel Pr and a side of the green sub-pixel Pg face the long side of the blue sub-pixel Pb. In an embodiment, the red sub-pixel Pr and the green sub-pixel Pg may be disposed in a first row, and the blue sub-pixel Pb may be disposed in a second row adjacent to the first row.

Alternatively, in another embodiment, the sub-pixel arrangement structure of the first pixel PX1 may be an S-stripe structure. For example, the blue sub-pixel Pb may be disposed in a first column, and the red sub-pixel Pr and the green sub-pixel Pg may be disposed in a second column adjacent to the first column. In this state, the blue sub-pixel Pb may be arranged in a rectangular shape having a long side in the second direction, for example, the +y direction or the −y direction, and the red sub-pixel Pr and the green sub-pixel Pg may each be arranged in a rectangular shape.

Alternatively, in another embodiment, the sub-pixel arrangement structure of the first pixel PX1 may be a stripe structure. For example, the red sub-pixel Pr, the green sub-pixel Pg, and the blue sub-pixel Pb may be arranged in the first direction, for example, the +x direction or the −x direction, or in the second direction, for example, the +y direction or the −y direction, parallel to one another. Alternatively, in another embodiment, the sub-pixel arrangement structure of the first pixel PX1 may be a Pentile structure.

Referring to FIG. 4, an edge CPE of the connection portion CP may extend in an extension direction of the connection portion CP. For example, when the connection portion CP extends in the first direction, for example, the +x direction or the −x direction, the edge CPE of the connection portion CP may also extend in the first direction, for example, the +x direction or the −x direction. Furthermore, when the connection portion CP extends in the second direction, for example, the +y direction or the −y direction, the edge CPE of the connection portion CP may extend in the second direction, for example, the +y direction or the −y direction.

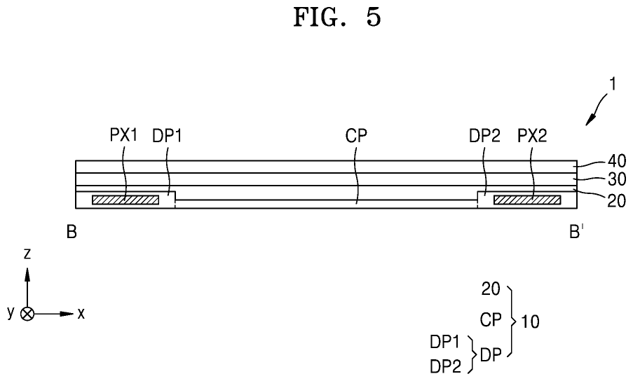

FIG. 5 is a schematic cross-sectional view of the display apparatus 1 according to an embodiment, taken along line B-B′ of FIG. 4.

Referring to FIG. 5, the display apparatus 1 may include the display panel 10, an optical functional layer 30, and the cover window 40.

The display panel 10 may include the display portion DP, the connection portion CP, and an encapsulation layer 20, and the display portion DP may include the first display portion DP1 and the second display portion DP2. Furthermore, the first pixel PX1 may be disposed in the first display portion DP1, and the second pixel PX2 may be disposed in the second display portion DP2. The first display portion DP1 and the second display portion DP2 may be connected to each other via the connection portion CP.

The encapsulation layer 20 may be disposed on the display portion DP and the connection portion CP. The encapsulation layer 20 may cover the first and second pixels PX1 and PX2. In an embodiment, the encapsulation layer 20 may include at least one inorganic layer. The at least one inorganic layer may include one or more inorganic insulating materials, such as a silicon oxide (SiOₓ), a silicon nitride (SiNₓ), a silicon oxynitride (SiOₓN_{y}), an aluminum oxide (Al₂O₃), a titanium oxide (TiO₂), a tantalum oxide (Ta₂O₅), a hafnium oxide (HfO₂), or a zinc oxide (ZnOₓ), and may be formed by a chemical vapor deposition (“CVD”) method and the like. ZnOₓ may include an oxide zinc (ZnO), and/or a peroxide zinc (ZnO₂).

In an embodiment, as illustrated in FIG. 5, the encapsulation layer 20 may be disposed on the display portion DP and the connection portion CP. Alternatively, although not illustrated, the encapsulation layer 20 may be disposed on the display portion DP only. In other words, the encapsulation layer 20 may be disposed on the display portion DP, and may not be disposed on the connection portion CP. Accordingly, the encapsulation layer 20 may have an opening corresponding to the connection portion CP.

The optical functional layer 30 may be disposed on the encapsulation layer 20. The optical functional layer 30 may include an antireflective layer. The antireflective layer may reduce the reflectivity of light (external light) incident on the display apparatus 1 from the outside. In an embodiment, the optical functional layer 30 may include a polarization film. Alternatively, the optical functional layer 30 may include a filter plate including a black matrix and color filters.

Although not illustrated in FIG. 5, a touch screen layer may be provided between the encapsulation layer 20 and the optical functional layer 30. The touch screen layer may obtain coordinate information according to an external input, for example, a touch event. The touch screen layer may include a touch electrode and touch wirings connected to touch electrode. The touch screen layer may sense an external input by a self-capacitance method or a mutual capacitance method.

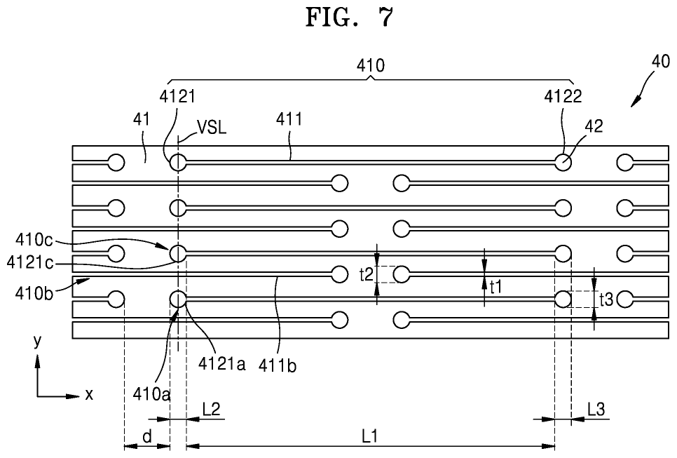

The cover window 40 may be disposed on the optical functional layer 30. The cover window 40 may function to protect the display panel 10. The cover window 40 may have a plurality of opening patterns 410, which is described below in FIG. 7.

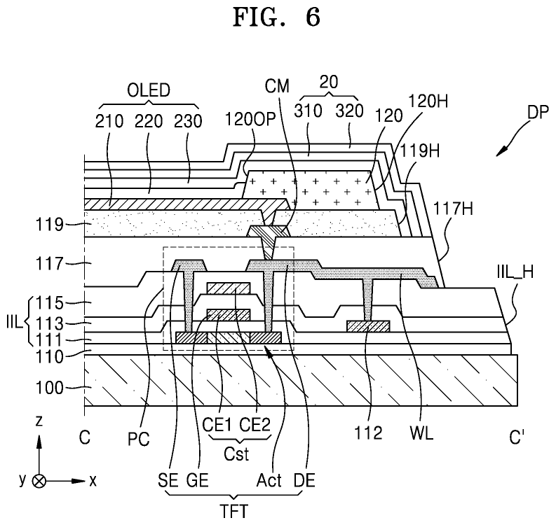

FIG. 6 is a schematic cross-sectional view of the display apparatus 1 according to an embodiment. In detail, FIG. 6 is a cross-sectional view taken along line C-C′ of FIG. 4.

In the following description, the stack structure of the display portion DP is described in detail.

Referring to FIG. 6, the display portion DP may include the substrate 100, a buffer layer 110, the pixel circuit PC, an inorganic insulating layer IIL, a first planarization layer 117, a connection electrode CM, a second planarization layer 119, the organic light-emitting diode OLED, a pixel defining layer 120, and the encapsulation layer 20.

The substrate 100 may include a base layer and a barrier layer on the base layer. In an embodiment, the substrate 100 may include a first base layer, a first barrier layer, a second base layer, and a second barrier layer, which are sequentially stacked. However, the disclosure is not limited thereto. At least one of the first barrier layer, the second base layer, and the second barrier layer may be omitted.

At least one of the first base layer and the second base layer may include polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, and the like.

The first barrier layer and the second barrier layer may be barrier layers to prevent infiltration of external foreign materials. The first barrier layer and the second barrier layer may prevent and reduce damage to the display portion DP. The first barrier layer and the second barrier layer may be a single layer or a multilayer including an inorganic insulating material, such as SiOₓ, SiNₓ, SiOₓN_{y}, or the like.

The buffer layer 110 may be disposed on the substrate 100. The buffer layer 110 may include an inorganic insulating material, such as SiOₓ, SiNₓ, and SiOₓN_{y}, and may be a single layer or a multilayer including the above-described inorganic insulating material. In an embodiment, the buffer layer 110 may be omitted.

The pixel circuit PC may include a thin film transistor TFT and the storage capacitor Cst. The thin film transistor TFT may include a semiconductor layer Act, a gate electrode GE, a source electrode SE, and a drain electrode DE. The storage capacitor Cst may include a lower electrode CE1 and an upper electrode CE2.

The semiconductor layer Act may be disposed on the buffer layer 110. The semiconductor layer Act may include polysilicon. Alternatively, the semiconductor layer Act may include amorphous silicon, an oxide semiconductor, an organic semiconductor, or the like. The semiconductor layer Act may include a channel region, and a drain region and a source region respectively disposed at opposite sides of the channel region.

The gate electrode GE may be disposed on the semiconductor layer Act. The gate electrode GE may overlap the channel region in a plan view. The gate electrode GE may include a low-resistance metal material. The gate electrode GE may include a conductive material including molybdenum (Mo), aluminum (Al), copper (Cu), titanium (Ti), or the like, and may be formed in a multilayer or a single layer including the above material.

The inorganic insulating layer IIL may include a first insulating layer 111, a second insulating layer 113, and a third insulating layer 115. The buffer layer 110 and the inorganic insulating layer IIL may each include a hole IIL_H at least partially overlapping the penetrating opening portion POP (see FIG. 4) in a plan view. In other words, the buffer layer 110 and the inorganic insulating layer IIL may be disposed in the display portion DP, and may not be disposed in the penetrating opening portion POP. Furthermore, the buffer layer 110 and the inorganic insulating layer IL may not be disposed in the connection portion CP. In other words, the buffer layer 110 and the inorganic insulating layer IIL may each include an opening overlapping the connection portion CP.

The first insulating layer 111 may be provided between the semiconductor layer Act and the gate electrode GE. The first insulating layer 111 may include one or more inorganic insulating materials, such as SiOₓ, SiNₓ, SiOₓN_{y}, Al₂O₃, TiO₂, Ta₂O₅, HfO₂, or ZnOₓ. ZnO may include ZnO and/or ZnO₂.

The second insulating layer 113 may cover the gate electrode GE. The second insulating layer 113 may include one or more inorganic insulating materials, such as SiOₓ, SiNₓ, SiOₓN_{y}, Al₂O₃, TiO₂, Ta₂O₅, HfO₂, or ZnOₓ. ZnO may include ZnO and/or ZnO₂.

The upper electrode CE2 may be disposed on the second insulating layer 113. The upper electrode CE2 may overlap the gate electrode GE thereunder in a plan view. In this state, the gate electrode GE and the upper electrode CE2 of the thin film transistor TFT overlapping each other with the second insulating layer 113 therebetween may form the storage capacitor Cst. In other words, the gate electrode GE of the thin film transistor TFT may function as the lower electrode CE1 of the storage capacitor Cst.

As such, the storage capacitor Cst and the thin film transistor TFT may overlap each other. However, the disclosure is not limited thereto. For example, the storage capacitor Cst may not overlap the thin film transistor TFT in another embodiment.

The upper electrode CE2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu, and may be a single layer or a multilayer including the above-described material.

The third insulating layer 115 may be disposed on the upper electrode CE2. The third insulating layer 115 may include one or more inorganic insulating materials, such as SiOₓ, SiNₓ, SiOₓN_{y}, Al₂O₃, TiO₂, Ta₂O₅, HfO₂, or ZnOₓ. ZnO may include ZnO and/or ZnO₂.

The source electrode SE and the drain electrode DE may each be located on the third insulating layer 115. The source electrode SE and the drain electrode DE may include a material exhibiting excellent conductivity. The source electrode SE and the drain electrode DE may each include a conductive material including Mo, Al, Cu, Ti, or the like, and may be formed in a multilayer or a single layer including the above material. For example, the source electrode SE and the drain electrode DE may each have a multilayer structure of Ti/Al/Ti.

A wiring WL may be located on the third insulating layer 115. In an embodiment, the wiring WL may be provided integrally with one of the source electrode SE and the drain electrode DE. However, the disclosure is not limited thereto. The wiring WL may be provided, as a separate constituent element, apart from the source electrode SE and the drain electrode DE in another embodiment.

In an embodiment, the wiring WL may be configured to transmit at least one of a power voltage, a data signal (or a data voltage), a scan signal (or a scan voltage), and a light-emitting control signal (or a light-emitting control voltage). Furthermore, the wiring WL may be electrically connected to a conductive layer 112 disposed thereunder. The wiring WL may be electrically connected to the conductive layer 112 via a contact hole defined in the second insulating layer 113 and the third insulating layer 115. The conductive layer 112 may be located on the same layer as that of the gate electrode GE and include the same material as that of the gate electrode GE.

Although not illustrated, an inorganic protection layer may be disposed above the thin film transistor TFT and the wiring WL. The inorganic protection layer may cover and protect the source electrode SE, the drain electrode DE, and the wiring WL.

The first planarization layer 117 may be disposed on the thin film transistor TFT and the wiring WL. The first planarization layer 117 may include an organic insulating material, for example, general purpose polymers, such as polymethylmethacrylate (“PMMA”) or polystyrene (“PS”), polymer derivatives having a phenolic group, acrylic polymer, imide-based polymer, aryl ether-based polymer, amide-based polymer, fluorine-based polymer, p-xylene-based polymer, vinyl alcohol-based polymer, and blends thereof.

The connection electrode CM may be disposed on the first planarization layer 117. The connection electrode CM may be connected to the drain electrode DE or the source electrode SE via a contact hole defined in the first planarization layer 117. The connection electrode CM may include a material exhibiting excellent conductivity. The connection electrode CM may include a conductive material including Mo, Al, Cu, Ti, or the like, and may be formed in a multilayer or a single layer including the above material. For example, the connection electrode CM may have a multilayer structure of Ti/Al/Ti. Although not illustrated, an upper wiring may be disposed on the first planarization layer 117. In an embodiment, the upper wiring may include the same material as that of the connection electrode CM.

The second planarization layer 119 may cover the connection electrode CM. The second planarization layer 119 may include an organic insulating material, for example, general purpose polymers, such as polymethylmethacrylate (PMMA) or polystyrene (PS), polymer derivatives having a phenolic group, acrylic polymer, imide-based polymer, aryl ether-based polymer, amide-based polymer, fluorine-based polymer, p-xylene-based polymer, vinyl alcohol-based polymer, and blends thereof.

Although not illustrated, a third planarization layer may be further disposed on the second planarization layer 119. In this case, an additional wiring may be further provided between the second planarization layer 119 and the third planarization layer.

The organic light-emitting diode OLED may be disposed on the second planarization layer 119. The organic light-emitting diode OLED may be disposed on the substrate 100, implementing a pixel. The organic light-emitting diode OLED may include a pixel electrode 210, an intermediate layer 220, and a counter electrode 230.

The pixel electrode 210 may be disposed on the second planarization layer 119. The pixel electrode 210 may be connected to the connection electrode CM via a contact hole defined in the second planarization layer 119. The pixel electrode 210 may include a conductive oxide, such as an indium tin oxide (“ITO”), an indium zinc oxide (“IZO”), a zinc oxide (ZnO), an indium oxide (In₂O₃), an indium gallium oxide (“IGO”), or an aluminum zinc oxide (“AZO”). Alternatively, the pixel electrode 210 may include a reflective film including Ag, Mg, Al, Pt, Pd, Au, Ni, Nd, Ir, Cr, or a compound thereof. Alternatively, the pixel electrode 210 may further include a film formed of ITO, IZO, ZnO, or In₂O₃ above/below the reflective film described above.

The pixel defining layer 120 having an opening 1200P for exposing at least part of the pixel electrode 210 may be disposed on the pixel electrode 210. The pixel defining layer 120 may include an organic insulating material and/or an inorganic insulating material. The opening 1200P defined in the pixel defining layer 120 may define a light-emitting area of the light emitted from the organic light-emitting diode OLED. For example, the width of the opening 1200P may correspond to the width of the light-emitting area. Furthermore, the width of the opening 1200P may correspond to the width of a sub-pixel.

The intermediate layer 220 may be disposed on the pixel electrode 210. The intermediate layer 220 may include a low-molecular weight or polymer material. When the intermediate layer 220 includes a low-molecular weight material, the intermediate layer 220 may have a structure in which a hole injection layer (“HIL”), a hole transport layer (“HTL”), an emission layer (“EML”), an electron transport layer (“ETL”), an electron injection layer (“EIL”), or the like are stacked in a single or composite structure, and may include various organic materials including copper phthalocyanine (CuPc), N,N′-di(naphthalene-1-yl)-N,N′-diphenyl-benzidine (NPB), tris-8-hydroxyquinoline aluminum (Alq₃), or the like. These layers may be formed by a vacuum deposition method.

When the intermediate layer 220 includes a polymer material, the intermediate layer 220 may have a structure including an HTL and an EML. In this state, the HTL may include PEDOT, and the EML may include a polymer material, such as a poly-phenylene vinylene (“PPV”)-based material and a polyfluorene-based material, and the like. The intermediate layer 220 may be formed by a screen printing method, an inkjet print method, a laser-induced thermal imaging method, or the like.

However, the intermediate layer 220 is not necessarily limited thereto, and may have various structures. The intermediate layer 220 may include an integrated layer across the pixel electrodes 210, or a layer patterned to correspond to each of the pixel electrodes 210.

The counter electrode 230 may be disposed on the intermediate layer 220. The counter electrode 230 may include a conductive material having a low work function. For example, the counter electrode 230 may include a (semi-)transparent layer including Ag, Mg, Al, Pt, Pd, Au, Ni, Nd, Ir, Cr, lithium (Li), Ca, an alloy thereof, or the like. Alternatively, the counter electrode 230 may further include a layer, such as ITO, IZO, ZnO or In₂O₃, on the (semi-)transparent layer including the above-described material. The intermediate layer 220 and the counter electrode 230 may be formed by a thermal deposition method.

A capping layer (not shown) for protecting the counter electrode 230 may be further disposed above the counter electrode 230. The capping layer may include an inorganic material, such as LiF, or/and an organic material.

In an embodiment, the encapsulation layer 20 may be disposed on the counter electrode 230. The encapsulation layer 20 may include at least one inorganic layer. The encapsulation layer 20 may include a first inorganic layer 310 and a second inorganic layer 320. Although not illustrated, the encapsulation layer 20 may further include an organic layer provided between the first inorganic layer 310 and the second inorganic layer 320.

In an embodiment, the first planarization layer 117, the second planarization layer 119, and the pixel defining layer 120 may respectively include holes 117H, 119H, and 120H at least partially overlapping the penetrating opening portion POP (see FIG. 4) in a plan view. The area of the hole 119H defined in the second planarization layer 119 may be greater than the area of the hole 117H defined in the first planarization layer 117. Furthermore, the area of the hole 120H defined in the pixel defining layer 120 may be greater than the area of the hole 119H defined in the second planarization layer 119.

In an embodiment, the tip end of the counter electrode 230 may be located on the first planarization layer 117 to be in direct contact with the first planarization layer 117. Furthermore, the tip end of the encapsulation layer 20 may be located on the first planarization layer 117 to be in direct contact with the first planarization layer 117.

FIG. 7 is a schematic plan view of the cover window 40 of the display apparatus 1, according to an embodiment.

Referring to FIG. 7, the cover window 40 may include a first member 41 and a second member 42.

The first member 41 may define the opening patterns 410 therein. Each of the opening patterns 410 may be formed to penetrate the first member 41 from an upper surface to a lower surface thereof.

The second member 42 having a modulus different from that of the first member 41 may be disposed in the opening patterns 410. The modulus of the first member 41 may be greater than the modulus of the second member 42. As the first member 41 has a modulus greater than the second member 42, the first member 41 has high wear resistance. As the second member 42 has a modulus less than the first member 41, the second member 42 is stretchable relative to the first member 41.

In the display apparatus 1 according to an embodiment, as the second member 42 having a low modulus is disposed in each of the opening patterns 410 formed in the first member 41 having a high modulus, the cover window 40 may have elasticity and simultaneously have improved wear resistance and impact resistance. In other words, in the display apparatus 1 according to an embodiment, the cover window 40 may have high elasticity, compared with a cover window formed of only a material having a high modulus, and relatively improved wear resistance and impact resistance, compared with a cover window formed of only a material having a low modulus.

As an example, the modulus of the first member 41 may be greater than 1 gigapascals (GPa) and less than 10 GPa. The modulus of the second member 42 may be greater than 0 GPa and less than 0.1 GPa.

The refractive index difference between the first member 41 and the second member 42 may be 0 to 3/1000. As the refractive indexes of the first member 41 and the second member 42 are matched or substantially similar with each other, the lowering of the optical characteristics, such as reflection and refraction, between the first member 41 and the second member 42 may be prevented.

The first member 41 may include glass, polyethylene terephthalate (PET), or transparent polyimide (PI), and the second member 42 may include thermoplastic polyurethane (TPU) or polydimethylsiloxane (PDMS).

Each of the opening patterns 410 formed in the first member 41 may include a first opening 411 extending in x direction, a second opening 4121 formed in one end of the first opening 411, and a third opening 4122 formed in the other end of the first opening 411 that is opposite to the one end of the first opening 411.

A length L1 of the first opening 411 in the x direction may be greater than each of a length L2 of the second opening 4121 in the x direction and a length L3 of the third opening 4122 in the x direction.

A width t1 of the first opening 411 in y direction perpendicular to the x direction may be less than each of a width t2 of the second opening 4121 and a width t3 of the third opening 4122 in y direction.

As such, comparing the second opening 4121 and the third opening 4122 at opposite ends of the first opening 411 with the first opening 411, in the x direction, the length L2 of the second opening 4121 and the length L3 of the third opening 4122 each are less than the length L1 of the first opening 411, and in y direction perpendicular to the x direction, the width t2 of the second opening 4121 and the width t3 of the third opening 4122 each are greater than the width t1 of the first opening 411. Thus, in a case in which the first opening 411 is extended in x direction, the concentration of stress at opposite ends of the first opening 411 may be alleviated.

The second opening 4121 and the third opening 4122 may have the same size. In other words, the length L2 of the second opening 4121 may be the same as the length L3 of the third opening 4122, and the width t2 of the second opening 4121 may be the same as the width t3 of the third opening 4122.

The second opening 4121 and the third opening 4122 may each have a circular shape, as an example, as illustrated in FIG. 7. However, the disclosure is not limited thereto, and the second opening 4121 and the third opening 4122 may have various shapes other than a circle.

The opening patterns 410 may be arranged such that the longitudinal direction of the first opening 411 is parallel to the x direction. An interval d between neighboring opening patterns in the x direction may be less than the length L1 of the first opening 411.

The opening patterns 410 may be arranged in y direction perpendicular to the x direction. In detail, referring to FIG. 7, in a case in which a first opening pattern 410a, a second opening pattern 410b, and a third opening pattern 410c are sequentially arranged in y direction, a second opening 4121a of the first opening pattern 410a and a second opening 4121c of the third opening pattern 410c are located on a virtual straight line VSL extending in y direction, and a first opening 411b of the second opening pattern 410b may be located between the second opening 4121a of the first opening pattern 410a and the second opening 4121c of the third opening pattern 410c.

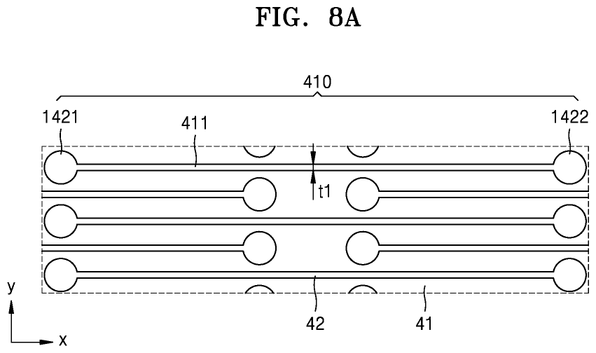

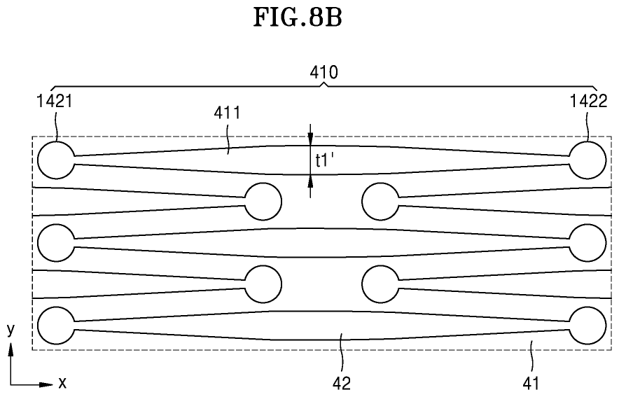

FIG. 8A is a schematic plan view showing a state of the cover window 40 of FIG. 7 before stretching. FIG. 8B is a schematic plan view showing a state of the cover window 40 of FIG. 7 after stretching.

As illustrated in FIG. 8A, in a state before the cover window 40 is stretched, the width t1 of the first opening 411 in y direction is constant in the x direction. When the cover window 40 is stretched in y direction, as illustrated in FIG. 8B, the first opening 411 is widened in y direction. In other words, a width t1′ of the first opening 411 of the cover window 40 of FIG. 8B that is stretched may be greater than the width t1 of the first opening 411 of the cover window 40 of FIG. 8A in y direction. As the opening patterns 410 are filled with the second member 42 having a low modulus, as the cover window 40 is stretched in x direction, the second member 42 may also be stretched.

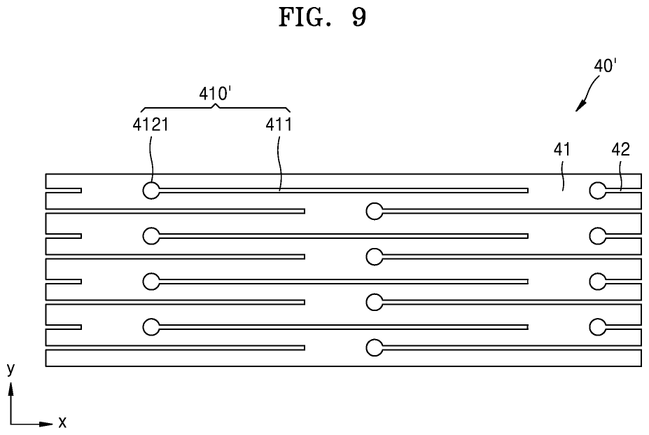

FIG. 9 is a schematic plan view of a cover window 40′ according to another embodiment.

Referring to FIG. 9, the cover window 40′ is different from the cover window 40 of FIG. 7 in terms of the shape of an opening pattern. In other words, while the cover window 40′ of FIG. 9 is the same as the cover window 40 of FIG. 7 in that an opening pattern 410′ of the cover window 40′ of FIG. 9 includes the first opening 411 extending in the x direction, the cover window 40′ of FIG. 9 is different from the cover window 40 of FIG. 7 in that the opening pattern 410′ of the cover window 40′ of FIG. 9 includes the second opening 4121 in only one end of the first opening 411, and no third opening is formed in the other end of the first opening 411.

Although the cover window 40′ of FIG. 9 includes a plurality of opening patterns 410′ each having the second opening 4121 formed in only one end of the first opening 411, the disclosure is not limited thereto. In another embodiment, the cover window 40′ may include a plurality of opening patterns each having a third opening (not shown) formed in only the other end of the first opening 411. Furthermore, the cover window 40′ may have a structure including both of an opening pattern having the second opening 4121 formed in only one end of the first opening 411 and an opening pattern having a third opening (not shown) formed in only the other end of the first opening 411.

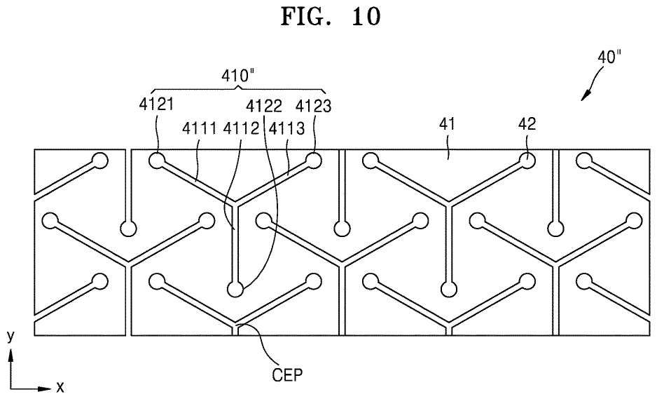

FIG. 10 is a schematic plan view of a cover window 40″ according to still another embodiment.

Referring to FIG. 10, the cover window 40″ may include the first member 41 and the second member 42 each having a different modulus from the other. The modulus of the first member 41 may be greater than the modulus of the second member 42. The characteristics of the first member 41 and the second member 42 may be the same as those of the cover window 40 of FIG. 7 described above.

An opening pattern 410″ may include a plurality of first openings 4111, 4112, and 4113 each having a common end converging at a center point CEP of the opening pattern 410″, and a plurality of second openings 4121, 4122, and 4123 formed in opposite ends opposite to the common end of the first openings 4111, 4112, and 4113, respectively. In other words, the first openings 4111, 4112, and 4113 may be connected to one another with respect to the center point CEP.

The width of each of the first openings 4111, 4112, and 4113 may be less that the width of each of the second openings 4121, 4122, and 4123. The first openings 4111, 4112, and 4113 may each have a straight-line shape, whereas the second openings 4121, 4122, and 4123 may each have a circular shape.

Each of the angles between the first openings 4111, 4112, and 4113 may be 120 degrees (°). Accordingly, the first openings 4111, 4112, and 4113 may each be stretchable in the x direction and/or in y direction, and also in a direction between the x direction and y direction.

As illustrated in FIG. 10, three openings are illustrated as the first openings 4111, 4112, and 4113, and the three first openings 4111, 4112, and 4113 with ends thereof connected to one another may be formed by maintaining an interval angle of 120° therebetween. Furthermore, each of the second openings 4121, 4122, and 4123 included in one opening pattern 410″ is formed to point toward a center point CEP of another opening pattern closest to the second opening. When the first openings 4111, 4112, and 4113 extend, the concentration of stress at each center point CEP may be alleviated.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a display panel comprising a display portion and a plurality of connection portions connected to the display portion and extending in different directions; and
a cover window disposed on the display panel,
wherein the cover window comprises:
a first member defining a plurality of opening patterns therein; and
a second member disposed in the plurality of opening patterns, and
a modulus of the first member is greater than a modulus of the second member.

2. The display apparatus of claim 1, wherein each of the plurality of opening patterns comprises a first opening extending in a first direction and a second opening formed in a first end of the first opening.

3. The display apparatus of claim 2, wherein each of the plurality of opening patterns further comprises a third opening formed in a second end of the first opening opposite to the first end of the first opening.

4. The display apparatus of claim 3, wherein the plurality of opening patterns are arranged parallel to the first direction, which is a longitudinal direction of the first opening.

5. The display apparatus of claim 4, wherein an interval between the plurality of opening patterns in the first direction is less than a length of the first opening in the first direction.

6. The display apparatus of claim 4, wherein a length of the second opening in the first direction is less than a length of the first opening in the first direction.

7. The display apparatus of claim 4, wherein a length of the third opening in the first direction is less than a length of the first opening in the first direction.

8. The display apparatus of claim 4, wherein, in a second direction perpendicular to the first direction, a width of the first opening is less than each of a width of the second opening and a width of the third opening.

9. The display apparatus of claim 4, wherein the plurality of opening patterns comprise a first opening pattern, a second opening pattern, and a third opening pattern, which are sequentially arranged and apart from one another in a second direction perpendicular to the first direction, and
a second opening of the first opening pattern and a second opening of the third opening pattern are on a virtual straight line in the second direction, and a first opening of the second opening pattern is between the second opening of the first opening pattern and the second opening of the third opening pattern.

10. The display apparatus of claim 4, wherein each of the second opening and the third opening has a circular shape.

11. The display apparatus of claim 4, wherein the second opening and the third opening have a same size.

12. The display apparatus of claim 1, wherein a modulus of the first member is greater than 1 gigapascal (GPa) and less than 10 GPa.

13. The display apparatus of claim 1, wherein a modulus of the second member is greater than 0 GPa and less than 0.1 GPa.

14. The display apparatus of claim 1, wherein a difference in a refractive index between the first member and the second member is 0 to 3/1000.

15. The display apparatus of claim 1, wherein the first member comprises glass, polyethylene terephthalate (PET), or transparent polyimide (PI).

16. The display apparatus of claim 1, wherein the second member comprises thermoplastic polyurethane (TPU) or polydimethylsiloxane (PDMS).

17. The display apparatus of claim 1, wherein each of the plurality of opening patterns comprise a plurality of first openings each having a common end converging at a center point of a corresponding opening pattern, and a plurality of second openings formed in opposite ends opposite to the common end of the plurality of first openings.

18. The display apparatus of claim 17, wherein an angle between the plurality of first openings is 120 degrees (°).

19. The display apparatus of claim 17, wherein each of the plurality of second openings is formed to point toward a center point of another opening pattern closest to each of the plurality of second openings.

20. A cover window for a display panel disposed on the display panel, the cover window comprising:
a first member defining a plurality of opening patterns therein; and
a second member disposed in the plurality of opening patterns,
wherein a modulus of the first member is greater than a modulus of the second member.
